(19) United States
(12) Patent Application Publication
(10) Pub. No.: US 2018/0138367 A1
(43) Pub. Date: May 17, 2018

(54) Nitride Light Emitting Diode and Growth Method

(71) Applicant: XIAMEN SANAN OPTOELECTRONICS TECHNOLOGY CO., LTD., Xiamen (CN)

(72) Inventors: Yung-ling LAN, Xiamen (CN); Chia-hung CHANG, Xiamen (CN); Chan-chan LING, Xiamen (CN); Wen-pin HUANG, Xiamen (CN)

(73) Assignee: XIAMEN SANAN OPTOELECTRONICS TECHNOLOGY CO., LTD., Xiamen (CN)

(21) Appl. No.: 15/870,899

(22) Filed: Jan. 13, 2018

Related U.S. Application Data
(63) Continuation of application No. PCT/CN2016/097870, filed on Sep. 2, 2016.

(30) Foreign Application Priority Data
Dec. 14, 2015 (CN) 201510921681.X

(51) Int. Cl. H01L 33/40; H01L 33/00

(52) U.S. Cl. CPC H01L 33/40; H01L 33/007

(57) ABSTRACT

A nitride light emitting diode includes a substrate and a nitride buffer layer, an n-type layer, a quantum well light emitting layer, and a p-type layer over the substrate. The n-type layer is a superlattice structure formed by alternating undoped AlGaN layers and n-type doped GaN layers. The Al component of the undoped AlGaN layer is controlled to produce first stress that offsets the second stress produced by the n-type doped GaN layer, reducing crystal defects and wrapping caused by impurity doping of the n-type layer. Growth temperature and pressure of the n-type layer are controlled such that thickness of the n-type doped GaN layer is greater than that of the undoped AlGaN layer to improve surface roughness of the undoped AlGaN layer and form an n-type doped GaN layer with a flat surface. Series resistance, crystal defects and wrapping, and optoelectronic properties of the device are therefore improved.

### CROSS-REFERENCE TO RELATED APPLICATIONS

The present application is a continuation of, and claims priority to, PCT/CN2016/097870 filed on Sep. 2, 2016, which claims priority to Chinese Patent Application No. 201510921681.X filed on Dec. 14, 2015. The disclosures of these applications are hereby incorporated by reference in their entirety.

### BACKGROUND

As application of the nitride semiconductor component extends widely, aside from high luminance, it is also important to increase static withstand voltage and reduce operation voltage. In particular, when large-size and high-power chips are applied in lighting and backlight sources, it requires to reduce voltage and improve light emitting luminance under rated driving current for effective reduction of power consumption.

Chinese Patent CN201310032282.9 discloses an epitaxial structure with large-size chip light effect and growth method thereof, which keeps total thickness of original n-type GaN and changes Si-doping method of the n-type GaN layer. Through periodic alternating growth of Si-doping and non-Si-doping, the Si-doped GaN is of low resistance, and non-Si-doped GaN is of high resistance. The n-type GaN with high and low resistance enhances lateral spreading capacity of electrons during current transmission. On the one hand, it solves current crowding, and reduces driving voltage; on the other hand, it homogenizes quantum well current to enlarge total light emitting area and improve luminance and light effects.

### SUMMARY

The inventors of the present disclosure have recognized that, although the aforesaid patent reduces chip driving voltage by solving current crowding to some extent, it fails to essentially improve poor electrical conductivity of GaN materials and meet market demands on LEDs with low energy consumption, and high driving voltage of chip due to high series resistance remains to be solved. Therefore, it is urgent to provide a technology capable of dramatically reducing working voltage of chip to meet market demands on low power and low energy consumption.

Given the above demands, the present invention provides a nitride light emitting diode and growth method thereof, where doping concentration of the n-type doped GaN layer is enhanced to above 1×10²⁰/cm³ to reduce series resistance and contact resistance of the light emitting diode and to reduce working voltage of the chip. Meanwhile, to improve crystal defect and wrapping due to high doping concentration of the n-type doped GaN layer, a superlattice structure with alternating undoped AlGaN layer and n-type doped GaN layer is formed under high temperature and low pressure; wherein, doping concentration of the n-type doped GaN layer is adjusted so that the first stress produced by the undoped AlGaN layer and the second stress produced by the n-type doped GaN layer different from the first stress offset each other, which reduces crystal defect and wrapping. On the other hand, thickness of the undoped AlGaN layer and the n-type doped GaN layer is controlled to adjust surface flatness of the superlattice structure; in this way, lattice quality of the superlattice structure is improved; lattice mismatch with subsequent epitaxial layer is reduced; and crack and wrapping due to large first stress are eliminated. Meanwhile, the n-type layer is a superlattice structure with alternating undoped AlGaN layer and n-type doped GaN layer to effectively disperse electrical field, and improve antistatic capacity.

In an aspect, a nitride light emitting diode is provided, including a substrate and a buffer layer, an n-type layer, a quantum well light emitting layer and a p-type layer over the substrate, wherein, the n-type layer is a superlattice structure formed by alternating undoped AlGaN layer and n-type doped GaN layer, wherein, the first stress produced by the undoped AlGaN layer offsets the second stress produced by the n-type doped GaN layer so as to reduce crystal defect and wrapping caused by n-type layer doping.

In some embodiments, the Al component of the undoped AlGaN layer is controlled such that the first stress produced and the second stress produced by the n-type doped GaN layer offset each other.

In some embodiments, doping concentration of the n-type doped GaN layer is higher than or equal to 1×10²⁰/cm³.

In some embodiments, doping concentration of the n-type doped GaN layer is 1×10²⁰/cm³-1×10²²/cm³.

In some embodiments, thickness of the n-type GaN layer is greater than that of the undoped AlGaN layer for adjusting surface flatness of the superlattice structure and improving crystal quality of the superlattice structure.

In some embodiments, thickness ratio of the undoped AlGaN layer and the n-type GaN layer is 1: 2-1:4.

In some embodiments, thickness of the n-type GaN layer is 5 Å-150 Å.

In some embodiments, Al component of the undoped AlGaN layer is 3%-8%.

In some embodiments, the n-type doping impurity is Si, Ge, Sn or Pb.

In some embodiments, number of cycles of the superlattice structure layer is 60-150. Meanwhile, the present invention also provides a fabrication method for a nitride light emitting diode, comprising: S1. providing a substrate; S2. growing a buffer layer over the substrate; S3. growing an n-type layer over the nitride buffer layer; S4. growing a quantum well light emitting layer and a p-type layer over the N-type layer; wherein, the n-type layer in step S3) is a superlattice structure with alternating undoped AlGaN and n-type doped GaN layer, wherein, the first stress produced by the undoped AlGaN layer offsets the second stress produced by the n-type doped GaN layer, thereby reducing crystal defect and wrapping caused by doping of the N-type layer.

In some embodiments, the Al component of the undoped AlGaN layer is controlled so that the first stress produced by the undoped AlGaN layer and the second stress produced by the n-type doped GaN layer offset each other.

In some embodiments, temperature of the reaction chamber during epitaxial growth is higher than 1050° C., and pressure is below 100 torr.

In some embodiments, doping concentration of the n-type doped GaN layer is higher than or equals to 1×10²⁰/cm³, and further, the doping concentration scope is 1×10²⁰/cm³-1×10²²/cm³.

In some embodiments, thickness of the n-type GaN layer is greater than that of the undoped AlGaN layer for adjusting surface flatness of the superlattice structure and improving crystal quality of the superlattice structure. Further, ratio thickness of the undoped AlGaN layer and the n-type GaN layer is 1: 2-1:4, wherein, thickness of the n-type GaN layer is 5 Å-150 Å.

In some embodiments, Al component of the AlGaN layer is 3%-8%.

In some embodiments, the n-type doping impurity is Si, Ge, Sn, or Pb.

In some embodiments, number of cycles of the superlattice structure layer is 60-150.

In another aspect, a light-emitting system is provided including a plurality of the nitride light-emitting diodes. The light-emitting system can be used in the field of, for example, lighting, display, signage, etc.

Various embodiments of the present disclosure can have one or more of the following advantageous effects: 1) the n-type layer is a superlattice structure with alternating undoped AlGaN layer and n-type doped GaN layer so that the first stress produced by the undoped AlGaN layer and the second stress produced by the n-type doped GaN layer offset each other, thus reducing crystal defect and wrapping of the n-type layer due to high doping concentration, such as dark spot on the surface and atomization; 2) doping concentration of the n-type layer is above 1×10²⁰/cm³, which reduces series resistance of the crystal, and further reduces driving voltage; 3) thickness of the undoped AlGaN layer and the n-type doped GaN layer is controlled to the extent that thickness of the undoped AlGaN layer is less than that of the n-type doped GaN layer, for adjusting surface flatness of the superlattice structure, thereby improving crystal quality of the superlattice structure, reducing lattice mismatch with subsequent epitaxial layer and crack and crystal wrapping due to large tensile stress; and 4) the superlattice structure formed by the undoped AlGaN layer and the n-type doped GaN layer can effectively disperse electric field so as to improve antistatic capacity and device stability.

### BRIEF DESCRIPTION OF THE DRAWINGS

The accompanying drawings, which are included to provide a further understanding of the invention and constitute a part of this specification, together with the embodiments, are therefore to be considered in all respects as illustrative and not restrictive. In addition, the drawings are merely illustrative, which are not drawn to scale.

FIG. 1 is a structural diagram of the nitride light emitting diode according to some embodiments.

FIG. 2 is a structural diagram of an N-type layer according to the present invention.

FIG. 3 is a growth flow diagram of the nitride light emitting diode according to some embodiments.

FIG. 4 is a structural diagram of a nitride light emitting diode formed according to the growth process of the nitride light emitting diode.

In the drawings: 10: substrate; 20: buffer layer; 30: u-GaN layer; 40: n-type layer; 41: undoped AlGaN layer; 42: n-type doped GaN layer; 50: quantum well light emitting layer; 60: p-type layer; 70: n electrode; 80: p electrode.

### DETAILED DESCRIPTION

Various embodiments of the present disclosure will be described in detail with reference to the accompanying drawings and embodiments.

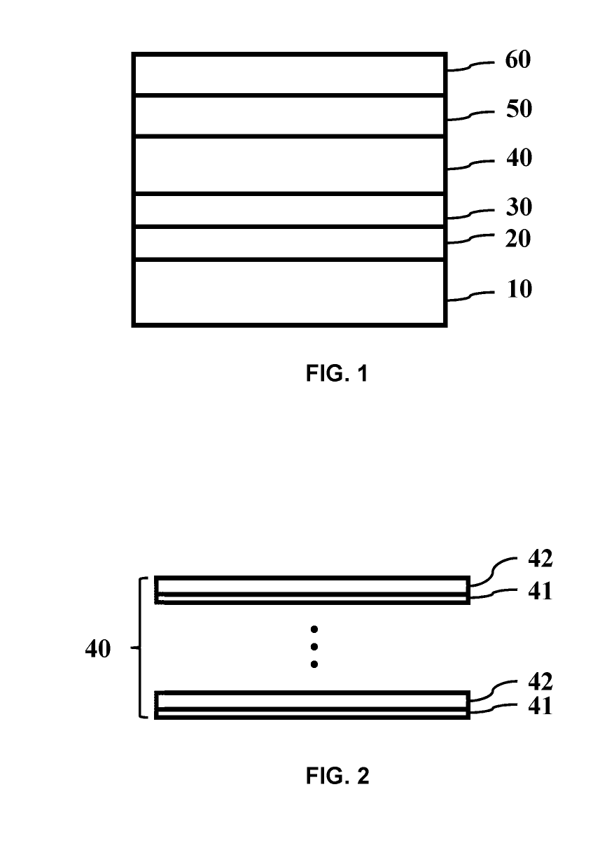

Referring to FIG. 1, a nitride light emitting diode comprises a substrate 10, and a nitride buffer layer 20, an n-type layer 40, a quantum well light emitting layer 50 and a p-type layer 60 over the substrate 10. In this embodiment, the nitride light emitting diode also comprises a u-GaN layer 30 between the nitride buffer layer 20 and the n-type layer 40, wherein, the substrate 10 can be any one of a sapphire plain substrate, a sapphire patterned substrate, a SiC substrate, a GaN substrate, a Si substrate, a glass substrate or a metal substrate; the nitride buffer layer 20 is a single-layer structure or a superlattice structure, and the component material is one or more of GaN, AlN, AlGaN or AlxMyGal-x-yN (x>0,y>0), where, M is In, Si or metal; and the p-type layer 60 is an Mg-doped GaN layer.

In the prior art, in the n-type layer 40 of epitaxial growth, the n-type doping concentration is generally less than 1×1019/cm3, because when n-type doping is higher than 1×10²⁰/cm3, the crystal would appear surface defect and wrapping, such as dark spot and atomization; as doping concentration increases, series resistance of the n-type layer 40 decreases, thus further decreasing voltage of the overall light emitting diode. Therefore, given the reversed impact of the doping concentration on the crystal quality and the series resistance, some embodiments of the present disclosure solve the important problem of decreasing surface defect and wrapping of the crystal while increasing doping concentration to reduce series resistance.

Referring to FIG. 2, to solve the surface defect and wrapping of the crystal when doping concentration is high, such as dark spot and atomization, in this embodiment, the n-type layer 40 is a superlattice structure with alternating undoped AlGaN layer 41 and n-type doped GaN layer 42, wherein, the first stress produced by the undoped AlGaN layer 41 and the second stress produced by the n-type doped GaN layer 42 in the superlattice structure offset each other, so as to reduce crystal defect and wrapping of the n-type layer due to doping, wherein, the n-type doping material is Si, Ge, Sn or Pb. In this embodiment, Si is preferred. The first stress and the second stress are of same or different stress. In this embodiment, the first stress produced by the undoped AlGaN layer 41 and the second stress produced by the n-type doped GaN layer 42 are different, where the first stress is tensile stress, and the second stress is pressure stress.

Referring further to FIG. 2, tensile stress produced by the undoped AlGaN layer 41 increases as Al component increases, and pressure stress produced by the n-type doped GaN layer 42 increases as Si doping concentration and thickness increase. Therefore, in this embodiment, Al component of the undoped AlGaN layer 41, Si concentration of the n-type doped GaN layer 42 and thickness of the n-type doped GaN layer 42 and the undoped AlGaN layer 41 are adjusted so that the tensile stress produced by the undoped AlGaN layer 41 and the pressure stress produced by the n-type doped GaN layer 42 offset each other. Specifically, Al component of the undoped AlGaN layer 41 is 3%-8%, and Si doping concentration is 1×10²⁰/cm3-1×10²²/cm3. As Si doping of the n-type doped GaN layer 42 is higher than common 1×10¹⁹/cm3, the n-type GaN layer 42 and the undoped AlGaN layer 41 in one circle are of thin layer structure so that pressure stress produced by the n-type GaN layer 42 and tensile stress produced by the undoped AlGaN layer 41 in one circle can be completely released and offset each other; specifically, the n-type GaN layer 42 is 5 Å-150 Å thick, thickness ratio of the undoped AlGaN layer 41 and the n-type GaN layer 42 is 1: 2-1:4; number of cycles of the superlattice structure with the undoped AlGaN layer 41 and the n-type doped GaN layer 42 is set to 60-150 without changing conventional total thickness of the N-type layer 40 (in general 1 μm-2.5 μm). Thickness of the n-type GaN layer 42 is larger than that of the undoped AlGaN layer 41. In one circle, an n-type doped GaN layer 42 with flat surface is formed to adjust the surface flatness of the superlattice structure, and to inhibit lattice defect extension; on the other hand, tensile stress produced by the undoped AlGaN layer 41 is so high that pressure stress produced by the n-type doped GaN layer 42 cannot be offset, thus producing cracks.

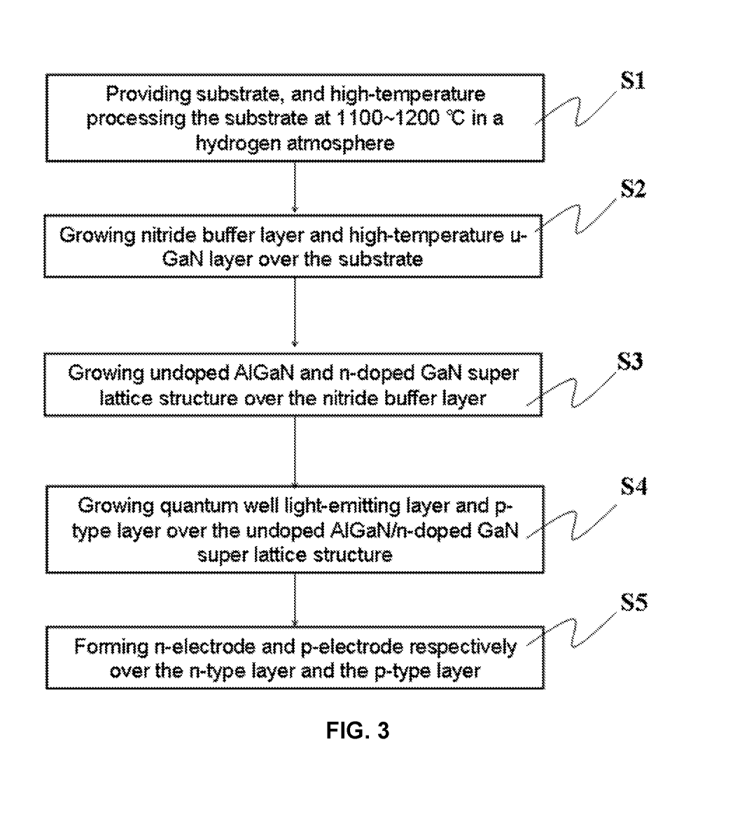

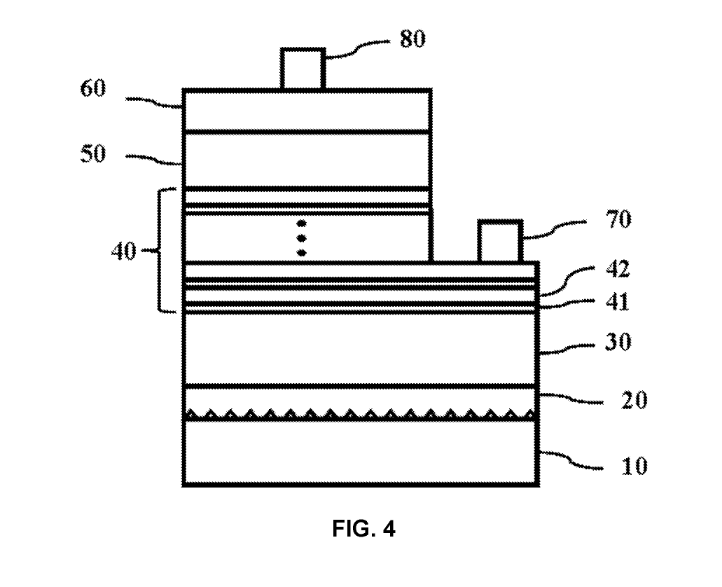

Referring to FIGS. 3-4, to fabricate an aforesaid nitride light emitting diode, the embodiment provides a growth method, specifically: S1. provide a substrate 10; S2. grow a nitride buffer layer 20 over the substrate 10; S3. grow an n-type layer 40 over the nitride buffer layer 20; S4. grow a quantum well light emitting layer 50 and a p-type layer 60 over the n-type layer 40.

The n-type layer 40 formed in step S3 is a superlattice structure with alternating undoped AlGaN 41 and n-type doped GaN layer 42, wherein, the first stress produced by the undoped AlGaN layer 41 and the second stress produced by the n-type doped GaN layer 42 different from the first stress in the superlattice structure offset each other, thus reducing crystal defect and wrapping of the N-type layer 40 due to doping.

In this embodiment, step S1 also comprises high-temperature treatment of the substrate 10 under 1100-1200° C. hydrogen atmosphere to remove impurity on surface of the substrate 10; in general, step S4) is followed by chip fabrication process; for example, an n electrode 70 and a p electrode 80 are fabricated over the n-type layer 40 and the p-type layer 60 through coating, development, etching and deposition.

In this embodiment, it is preferred to grow a GaN buffer layer 20 over the sapphire substrate under low temperature. As the sapphire substrate and the GaN are of heterostructure, to further buffer the extension of lattice mismatch defect between the substrate and the GaN epitaxial layer, a high-temperature u-GaN layer 30 is grown after step S2) to improve bottom lattice quality. Then, continue to grow a superlattice structure of undoped AlGaN and n-type doped GaN over the u-GaN layer 30. Adjust the reaction chamber temperature to above 1,050° C. and pressure below 100 torr. Control the carrier gas flow. Grow the undoped AlGaN layer 41, and then grow an n-type doped GaN layer 42 with n-type doped concentration higher than or equal to 1×10²⁰/cm3 over the undoped AlGaN layer 41, and repeat this for 60-150 cycles. Wherein, the first stress produced by the undoped AlGaN layer 41 and the second stress produced by the n-type doped GaN layer 42 different from the first stress offset each other to reduce the crystal defect and wrapping caused by n-type doped concentration higher than or equal to 1×10²⁰/cm3. Other parameters and functional mechanisms of the structure produced by this method are same as those aforesaid, which are not repeated.

In this embodiment, the doping concentration of the n-type layer 40 is controlled higher than or equal to 1×10²⁰/cm3, to substantially reduce series resistance of the light emitting diode, and further reduce driving voltage of the chip. Then, the n-type layer 40 with single growth method is changed to a superlattice structure formed by a undoped AlGaN layer 41 and an n-type doped GaN layer 42 to reduce crystal defect and wrapping caused by n-type doping concentration higher than or equal to 1×10²⁰/cm3 so as to further improve photoelectric property of the device.

Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A nitride light emitting diode comprising:
a substrate and a buffer layer;
an n-type layer;
a quantum well light emitting layer and a p-type layer over the substrate,
wherein:
the n-type layer is a superlattice structure formed by alternating undoped AlGaN layers and n-type doped GaN layers; and
a first stress produced by the undoped AlGaN layers offsets a second stress produced by the n-type doped GaN layer.

2. The nitride light emitting diode of claim 1, wherein Al component of the undoped AlGaN layer is adjusted such that the first stress produced by the undoped AlGaN layer and the second stress produced by the n-type doped GaN layer offset each other.

3. The nitride light emitting diode of claim 1, wherein a doping concentration of the n-type doped GaN layer is higher than or equal to 1×10²⁰/cm³.

4. The nitride light emitting diode of claim 1, wherein a thickness of the n-type doped GaN layer of the superlattice structure is greater than that of the undoped AlGaN layer, to thereby adjust surface flatness of the superlattice structure and improve crystal quality of the superlattice structure.

5. The nitride light emitting diode of claim 1, wherein a thickness ratio of the undoped AlGaN layer and the n-type doped GaN layer is 1:2-1:4.

6. The nitride light emitting diode of claim 1, wherein a thickness of the n-type doped GaN layer is 5 Å-150 Å.

7. The nitride light emitting diode of claim 1, wherein Al component in the undoped AlGaN layer is 3%-8%.

8. The nitride light emitting diode of claim 1, wherein number of cycles of the superlattice structure is 60-150.

9. A method of growing a nitride light emitting diode, the method comprising:
S1: providing a substrate;
S2: growing a buffer layer over the substrate;
S3: growing an n-type layer over the nitride buffer layer; and
S4: continuing to grow a quantum well light emitting layer and a p-type layer over the n-type layer;
wherein:
the n-type layer formed in step S3) is a superlattice structure formed by alternating undoped AlGaN layers and n-type doped GaN layers; and
a first stress generated by the undoped AlGaN layers offsets a second stress generated by the n-type doped GaN layers.

10. The method of claim 9, wherein Al component of the undoped AlGaN layers is adjusted such that the first stress produced by the undoped AlGaN layers and the second stress produced by the n-type doped GaN layers offset each other.

11. The method of claim 9, wherein growth conditions of step S3 include: temperature is higher than 1050° C., and pressure is below 100 torr.

12. The method of claim 9, wherein doping concentration of the n-type doped GaN layer is higher than or equal to 1×10²⁰/cm³.

13. The method of claim 9, wherein a thickness of the n-type GaN layer is greater than that of the undoped AlGaN layer to thereby adjust surface flatness of the superlattice structure and improve crystal quality of the superlattice structure.

14. The method of claim 9, wherein component of the AlGaN layer is 3%-8%.

15. Alight-emitting system including a plurality of nitride light emitting diodes, each diode comprising:
a substrate and a buffer layer;
an n-type layer;
a quantum well light emitting layer and a p-type layer over the substrate,
wherein:
the n-type layer is a superlattice structure formed by alternating undoped AlGaN layers and n-type doped GaN layers; and
a first stress produced by the undoped AlGaN layers offsets a second stress produced by the n-type doped GaN layer.

16. The system of claim 15, wherein Al component of the undoped AlGaN layer is adjusted such that the first stress produced by the undoped AlGaN layer and the second stress produced by the n-type doped GaN layer offset each other.

17. The system of claim 15, wherein a doping concentration of the n-type doped GaN layer is higher than or equal to 1×10²⁰/cm³.

18. The system of claim 15, wherein a thickness of the n-type doped GaN layer of the superlattice structure is greater than that of the undoped AlGaN layer, to thereby adjust surface flatness of the superlattice structure and improve crystal quality of the superlattice structure.

19. The system of claim 15, wherein a thickness ratio of the undoped AlGaN layer and the n-type doped GaN layer is 1:2-1:4.

20. The system of claim 15, wherein:
a thickness of the n-type doped GaN layer is 5 Å-150 Å;
Al component in the undoped AlGaN layer is 3%-8%; and
number of cycles of the superlattice structure is 60-150.
